(19) United States
(12) Patent Application Publication
(10) Pub. No.: US 2010/0244286 A1
(43) Pub. Date: Sep. 30, 2010

(54) NANOCOMPOSITES FOR OPTOELECTRONIC DEVICES

(76) Inventor: Earl Vincent B. LAGSA, Cabuyao (PH)

Correspondence Address: Stallman c/o MoFo, 425 Market Street, San Francisco, CA, 94105-2482, US

(21) Appl. No.: 12/572,963

(22) Filed: Oct. 2, 2009

Related U.S. Application Data
(60) Provisional application No. 61/102,922, filed on Oct. 6, 2008.

(51) Int. Cl. H01L 23/28; C08K 5/5419; C08K 3/36; C08K 3/22; C08L 83/04; C08G 65/02; H01L 21/56

(52) U.S. Cl. 257/789; 524/265; 524/493; 524/497; 524/430; 524/432; 524/588; 524/612; 438/127; 257/E21.502; 257/E23.116

(57) ABSTRACT

Nanoparticles (<100 nm) and submicron particles (<400 nm) can be used as filler material to form a nanocomposite that can be used as an encapsulant for optoelectronic devices. These nanocomposites can function to reduce light scattering and increase thermal, mechanical and dimensional stability of the optoelectronic device. Such nanocomposites can also improve moisture barrier characteristics, lower the dielectric constant and increase resistivity of the optoelectronic device.

### PRIORITY CLAIM PROVISIONAL

This application claims priority to U.S. Provisional Application No. 61/102,922, filed Oct. 6, 2008, the disclosure of which is herein incorporated by reference for all purposes.

### TECHNICAL FIELD

The present application relates to nanocomposites that can be used as encapsulants for optoelectronic devices.

### BACKGROUND

There is continuing interest in improving the performance of various optoelectronic devices such as solid state emitters (e.g. laser diodes and LEDs) and solid state photo detectors (e.g. photodiodes and phototransistors). In these devices, the solid state element is typically mounted on a support or substrate and sealed with a polymer-based encapsulant (e.g. epoxies and mold compounds). The polymer encapsulant should be highly transmissive since the solid state device within the encapsulant is either emitting or detecting light.

Many of these devices operate in harsh environments. Therefore, there is need to create devices that are thermally and mechanically stable as well as moisture resistant. It is known that polymer encapsulants in general can be strengthened by the addition of inorganic particles such as a filler material. Such filler materials improve thermal and mechanical stability. This result in improved reliability and performance in terms of reflow soldering, solder heat resistance, temperature cycling, etc. However, typical particles, having diameters greater than one micron, tend to scatter light, making them unsuitable for use in encapsulants for emitting and detecting devices.

Today, there is a high level of interest in nanotechnology and the fabrication of nanoparticles, i.e., particles having a diameter of less than 100 nm. Such particles are now being used in many products. These small particles can be used as the filler material in an encapsulant. Because of their small size, less than the wavelength of visible light, an encapsulant of a composite including nanoparticles would not scatter light nearly as much as micron size particles. Further, these nanoparticles can function to increase thermal, mechanical and dimensional stability of the device. In addition, such a composite can improve moisture barrier characteristics, lower the dielectric constant and increase resistivity. Accordingly, an optoelectronic device packaged in an encapsulant with nanoparticles fillers will have improved strength while still having the desired transmission characteristics.

As reflected in some of the prior art cited below, nanoparticles have been used in certain optoelectronics devices. The subject invention relates to additional aspects of nanoparticle use with optoelectronic devices not believed to have been disclosed in the prior art.

### BRIEF SUMMARY

In one aspect of the subject invention, nanoparticles (<100 nm) and submicron particles (<400 nm) are used as fillers for making nanocomposites that are used to encapsulate optoelectronic devices. Loading of filler in an encapsulant may range from 0.01% to 90% by weight. Embodiments also provide for encapsulant to filler loading ratios where the encapsulant is 95-99.9% by weight of the nanocomposite and the filler is 0.01-5% by weight of the nanocomposite. Additional embodiments provide for encapsulate to filler ratios of 99.9% to 0.01%, 99.5% to 0.5%, 99% to 1%, and 97.5% to 2.5%. In some embodiments, the nanoparticles and submicron particles may be surface modified.

Encapsulants include optoelectronic-grade materials such as epoxy adhesives, mold compound, or silicone-based polymer.

Nanoparticles and submicron particles can include SiO₂, Al₂O₃, TiO₂, ZnO, ZrO₂, MgO, YtO, CeOx, Sb₂O₃, SnO, Bi₂O₃, ZnSe, ZnS, CsI, AlN, TiN, GaN, SiN, fused silica, borosilicate, quartz, or colored filtering glass.

Surface modification of the particles includes organic coatings and can be achieved using coupling agents such as silanols and silanes. In certain aspects of the invention, the surface modifications are 3-methacryloxypropyltrimethoxysilane, octyltrimethoxysilane, or 3-glycidyloxypropyl trimethoxysilane (GTS).

An additional embodiment provides for a method of encapsulating an optoelectronic device with a nanocomposite of the subject invention. Encapsulating techniques can be casting, molding, chip on board (COB), coating, glob top, sealing, or potting.

Another aspect provides for an optoelectronic device fabricated with a nanocomposite of the subject invention. The optoelectronic device can be a photodetector, photodiode, phototransistor, photodarlington, PhotoIC, PIN diode, laser diode, light emitting diode (LED), infrared emitting diode (IRED), avalanche photodiode (APD), silicon avalanche photodiode (Si APDs), high performance sensor (HPS), or semiconductor integrated circuit (IC).

In one aspect of the subject invention, surface modified silica (SiO₂) nanoparticles (<100 nm) and submicron silica (SiO₂) particles (<400 nm) are used as fillers for making nanocomposites that are used to encapsulate a photodetector or light emitting diode. Alternative particles are fused silica or borosilicates. Loading of filler in the encapsulant is from 0.01% to 80% by weight. Embodiments also provide for loading ratios where the encapsulant is 95-99.9% and the filler is 0.01-5%. Surface modification of the particles includes organic coatings and can be achieved using coupling agents such as silanols and silanes. Another embodiment provides for a method of encapsulating an optoelectronic device with a nanocomposite of the subject invention. Encapsulating techniques can be casting, molding, chip on board (COB), coating, glob top, sealing, or potting.

In another aspect of the subject invention, surface modified alumina (Al₂O₃) nanoparticles (<100 nm) and submicron alumina (Al₂O₃) particles (<400 nm) are used as fillers for making nanocomposites that are used to encapsulate a photodetector. Alternative particles are TiO₂, ZrO₂, MgO, YtO, CeOx, Sb₂O₃, SnO, Bi₂O3, ZnSe, ZnS, CsI, AlN, TiN, GaN, SiN, inorganic oxides, and inorganic nitrides. Loading of filler in the encapsulant is from 0.01% to 80% by weight. Embodiments also provide for loading ratios where the encapsulant is 95-99.9% and the filler is 0.01-5%. Surface modification of the particles includes organic coatings and can be achieved using coupling agents such as silanols and silanes. Another embodiment provides for a method of encapsulating an optoelectronic device with a nanocomposite of the subject invention. Encapsulating techniques can be casting, molding, chip on board (COB), coating, glob top, sealing, or potting.

In yet another aspect of the subject invention, surface modified titanium dioxide (TiO₂) nanoparticles (<100 nm) and titanium dioxide (TiO₂) submicron particles (<400 nm) are used as fillers for making nanocomposites that are used to encapsulate a photodetector. Alternative particles are Al₂O₃, ZrO₂, MgO, YtO, CeOx, Sb₂O₃, SnO, Bi₂O3, ZnSe, ZnS, CsI, AlN, TiN, GaN, SiN, inorganic oxides, and inorganic nitrides. Loading of filler in the encapsulant is from 0.01% to 80% by weight. Embodiments also provide for loading ratios where the encapsulant is 95-99.9% and the filler is 0.01-5%. Surface modification of the particles includes organic coatings and can be achieved using coupling agents such as silanols and silanes. Another embodiment provides for a method of encapsulating an optoelectronic device with a nanocomposite of the subject invention. Encapsulating techniques can be casting, molding, chip on board (COB), coating, glob top, sealing, or potting.

In another aspect of the subject invention, surface modified zinc oxide (ZnO) nanoparticles (<100 nm) and submicron zinc oxide (ZnO) particles (<400 nm) are used as fillers for making nanocomposites that are used to encapsulate a photodetector or light emitting diode. Loading of filler in the encapsulant is from 0.01% to 80% by weight. Embodiments also provide for loading ratios where the encapsulant is 95-99.9% and the filler is 0.01-5%. Surface modification of the particles includes organic coatings and can be achieved using coupling agents such as silanols and silanes. Another embodiment provides for a method of encapsulating an optoelectronic device with a nanocomposite of the subject invention. Encapsulating techniques can be casting, molding, chip on board (COB), coating, glob top, sealing, or potting.

In still another object of the subject invention, surface modified or unmodified nanoparticles (<100 nm), submicron particles (<400 nm) and micron size (400 nm to 100 μm) particles derived from commercially available colored filtering materials such as colored glasses are used as fillers for making nanocomposites that are used to encapsulate a photodetector or light emitting diode. Loading of filler in the encapsulant is from 0.01% to 90% by weight. Embodiments also provide for loading ratios where the encapsulant is present at between 95-99.9% and the filler is present at between 0.01-5%. Surface modifications of the particles include organic coatings and can be achieved using coupling agents such as silanols and silanes. Another embodiment provides for a method of encapsulating an optoelectronic device with a nanocomposite of the subject invention. Encapsulating techniques can be casting, molding, chip on board (COB), coating, glob top, sealing, or potting.

### BRIEF DESCRIPTION OF THE DRAWINGS

FIG. 1 illustrates an exemplary development and process flow chart of a nanocomposite filler for optoelectronic device packaging.

FIG. 2 illustrates an exemplary Type I direct mixing process flow chart.

FIG. 3 illustrates an exemplary particle-solvent pre-mixing process flow chart.

FIG. 4 illustrates an exemplary Type II direct mixing process flow chart.

FIG. 5 illustrates an exemplary mixing process flow chart in alcohol solution through rotary evaporation of solvent.

FIGS. 6A-6G shows Scanning Electron Microscopy (SEM) images and measured particle sizes of balled milled particles: (a) as-received silica, (b) fused silica (29 hrs of ball milling), (c) silica (36 hrs of ball milling), (d) silica (48 hrs of ball milling), (e) commercially available silica nanoparticles 99.5% APS 15 nm (f) R711, and (g) R805.

FIGS. 7A-7C illustrate exemplary nanoparticle surface modification process flow chart through (a) autoclave, (b) reflux, and (c) oven cure.

FIG. 8 shows the transmission spectra for conventional filler versus exemplary nanocomposite fillers.

FIGS. 9A-E illustrates nanocomposite encapsulants for exemplary optoelectronic device packaging, including a through-hole device, a surface mount device, other devices (header, substrate, chip on board, PCB), coating/glob top on optoelectronic chip, and dispersion

FIG. 10 shows a sample optoelectronic device packaged in 0.5% fused silica filler (<400 nm diameter) in polymer matrix.

FIGS. 11A-11E illustrate transmission spectra for modified and unmodified filler nanocomposite encapsulants for various filler weight loads.

FIGS. 12A-12D illustrate characterization measurements of exemplary modified and unmodified filler nanocomposite encapsulants described herein.

### DETAILED DESCRIPTION OF THE INVENTION

Nanocomposites and methods of the present invention can provide a significant improvement in terms of thermo-mechanical stability of optoelectronic packages by employing nanoparticles and submicron particles as fillers for optoelectronic encapsulants (molding compound and cast epoxy) without affecting optical performance.

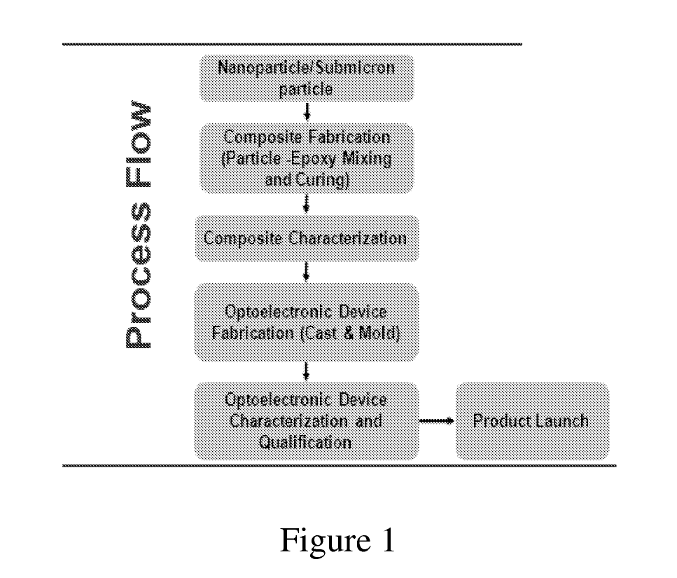

FIG. 1 shows an exemplary development and process flow of a nanoparticle-based composite encapsulant for optoelectronic packaging. The embodiment of this invention starts with selecting the raw materials: particles and an encapsulant. The particles may include nanoparticles (<100 nm) and/or submicron particles (<400 nm) can be derived from SiO₂, Al₂O₃, TiO₂, ZnO, ZrO₂, MgO, YtO, CeOx, Sb₂O₃, SnO, Bi₂O₃, ZnSe, ZnS, CsI, AlN, TiN, GaN, SiN, fused silica, borosilicate, or quartz. Nanoparticles and submicron particles may also be derived from absorptive, transmittive, colored filtering, or optical filtering glasses which can add optical filtering properties. By way of example, an embodiment provides for commercially-available glasses of Schott and Corning such as but not limited to BK7™, BG18™, and RG650™.

Nanoparticles and submicron particles can be fabricated through any method as long as the required particle sizes are met. By way of example, agate and planetary ball-milling of larger particles may be employed in the particle fabrication process. Additionally, other methods such as through silicate solutions, colloidal methods, sol-gel methods, vapor phase deposition, plasma assisted deposition, gas condensation, laser ablation, thermal and ultrasonic decomposition, Stranski-Krastanov growth, thermal spraying, or combinations thereof, may be employed for nanoparticle fabrication and/or submicron particle fabrication.

The encapsulants may include any optoelectronic-grade cast epoxies or mold compounds. Commercially available examples include, but are not limited to, Aptek, Nippon Pelnox, Nitto Denko, Hysol, Henkel, Huawei, Ablestik, Epocal, Epotek, Ablestik, Gold Epoxy (GE), and APM Technica. A dye or filtering pigment may be added to such encapsulants.

For the mix ratio of encapsulant to nanoparticle and submicron particle filler, the loading (as a weight percent), of the encapsulant to the filler can range from 20-99.99% encapsulant to 0.01-80% filler. In preferred embodiments the loading weight percent ranges from 95-99.9% encapsulant to 0.01-5% filler. Embodiments also provide for ratios of 99.9% encapsulant to 0.10% filler, 99.5% encapsulant to 0.5% filler, 99% encapsulant to 1% filler, and 97.5% encapsulant to 2.5% filler.

The second step in the process of FIG. 1 is nanocomposite fabrication. This step involves the particle-encapsulant mixing and curing. Mixing can be achieved by direct mixing of fillers and encapsulant. Mixing can also be achieved by dispersing fillers in solvents or anti-flocculants and mixing with the encapsulant. Solvents or anti-flocculants include but are not limited to acetone, methanol, ethanol, toluene, and propanol. Fillers are 0.1%-75% by weight in solvents or anti-flocculants. Dispersion of fillers in solvents or anti-flocculants is by any method including but not limited to centrifugal mixing, agitation, high shear mixing, or conventional rotary mixing.

Two types of mixing that are suitable for practice with certain embodiments of the subject invention are Type I direct mixing and Type II mixing via solvents. Other mixing methods are also applicable as long as substantial homogeneity of the mixture is attained.

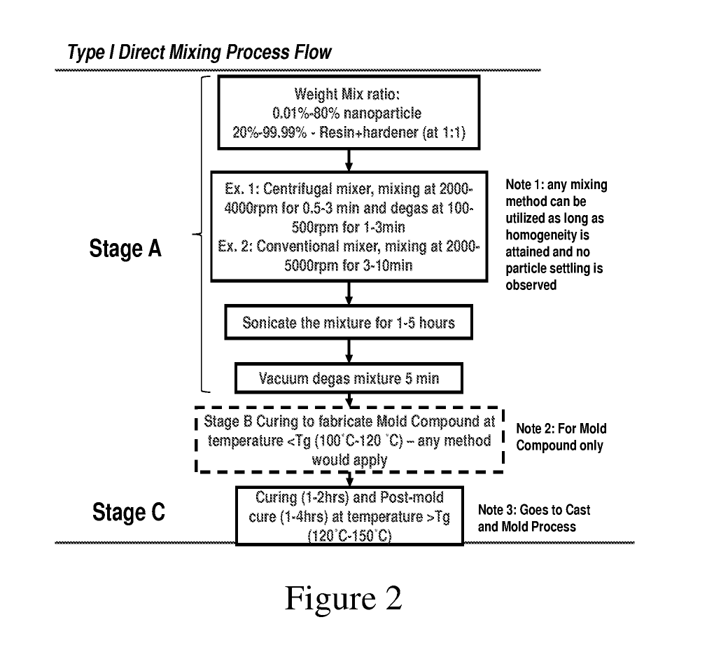

An exemplary Type I direct mixing process flow is shown in FIG. 2. The filler and encapsulant (resin and hardener) are weighted to attain the required mix ratio. Mixing techniques such as but not limited to centrifugal mixing, agitation, and conventional rotary mixing can be utilized as long as homogeneity of the mixture is attained. Mixing is followed by mixture sonication and vacuum degassing. The first few steps form part of Stage A of encapsulant or thermoset curing. For cast technology, mixture can be dispensed and cured. For mold technology, mixtures are Stage B cured by any method for mold compound preparation. Methods of mold compound preparation include but are not limited to partial curing, pulverization, compression and cold storage. Stage C curing then happens during the molding process.

In several studies, it was shown that nanoparticles can be pre-mixed with organic solvents such as but not limited to acetone, methanol, ethanol, propanol, and toluene. This is done in order to prevent particle agglomeration. Agglomeration is not favorable in nanocomposite fabrication since it increases the effective particle size.

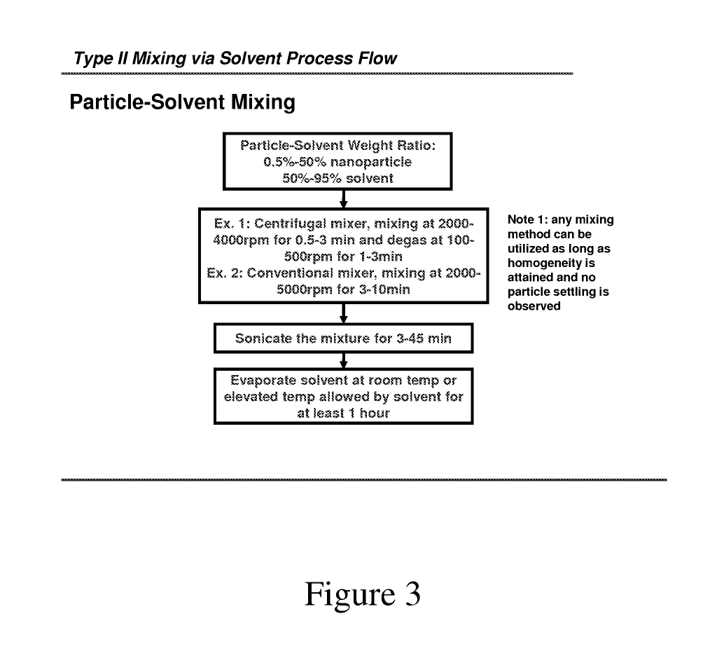

FIG. 3 shows an exemplary particle-solvent pre-mixing process flow. The nanoparticle/submicron filler and solvent are weighted to attain the desired mix ratio. Mixing techniques such as but not limited to centrifugal mixing, agitation, and conventional rotary mixing can be utilized as long as the homogeneity of the mixture is attained. Mixing is followed by mixture sonication and degassing to allow evaporation of most solvent at an allowable temperature by the solvent.

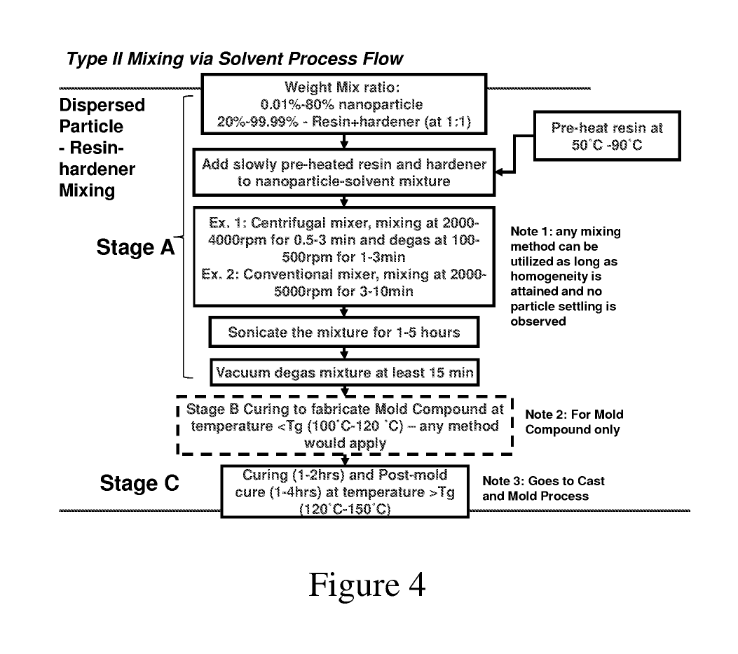

An exemplary Type II mixing process flow is shown in FIG. 4. The nanoparticle/submicron filler and encapsulant (resin and hardener) are weighted to attain the desired mix ratio. Resin is pre-heated at 50° C.-90° C. temperature prior to mixing. The pre-heated resin and hardener are then slowly added to the nanoparticle-solvent mixture. Mixing techniques such as but not limited to centrifugal mixing, agitation, and conventional rotary mixing can be utilized as long as the homogeneity of the mixture is attained. Mixing is followed by mixture sonication and vacuum degassing. The first few steps form part of the Stage A of thermoset curing. For cast technology, the mixture can be dispensed and cured. For mold technology, mixtures are Stage B cured by any method for mold compound preparation (such as partial curing, pulverization, pelletizing and cold storage). Stage C curing then happens during the molding process.

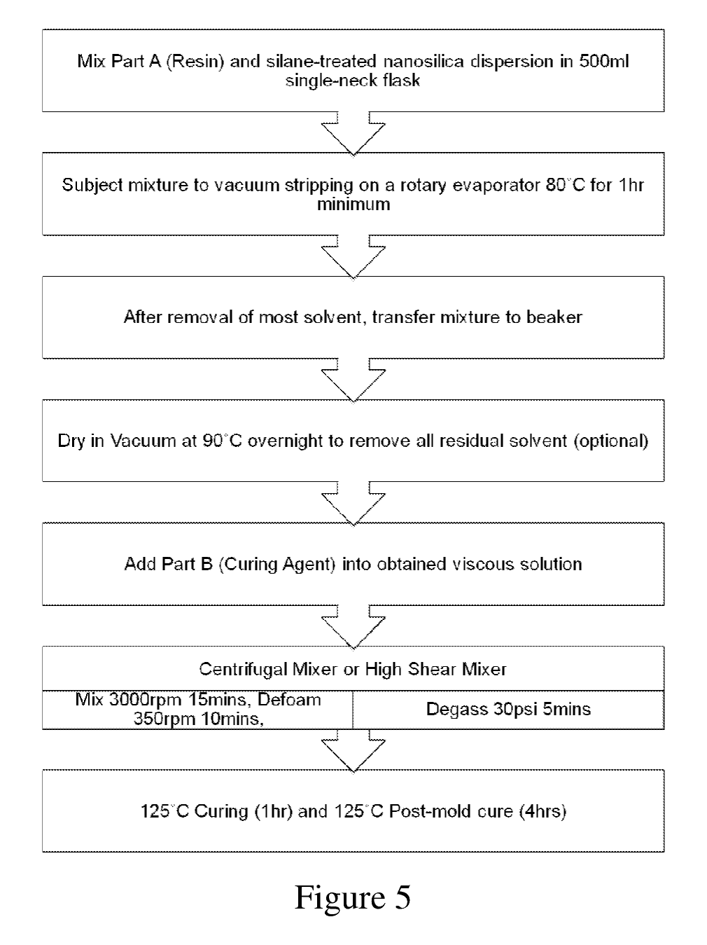

FIG. 5 illustrates an exemplary nanocomposite fabrication method using rotary evaporation for solvent removal. Generally, the exemplary method includes mixing resin and silane-treated nanosilica. The mixture may then be subject to vacuum stripping on a rotary evaporator, e.g., at 80° C. for 1 hour. After removal of most or substantially all of the solvent, the mixture may then be optionally dried in a vacuum, e.g., at 90° C. for 12-24 hours, to remove remaining residual solvent. A curing agent may then be added to the viscous solution. The curing agent and viscous solution may be mixed, e.g., via a centrifugal mixer or high shear mixer. The resulting nanocomposite material may be cured, e.g., at 125° C. as illustrated.

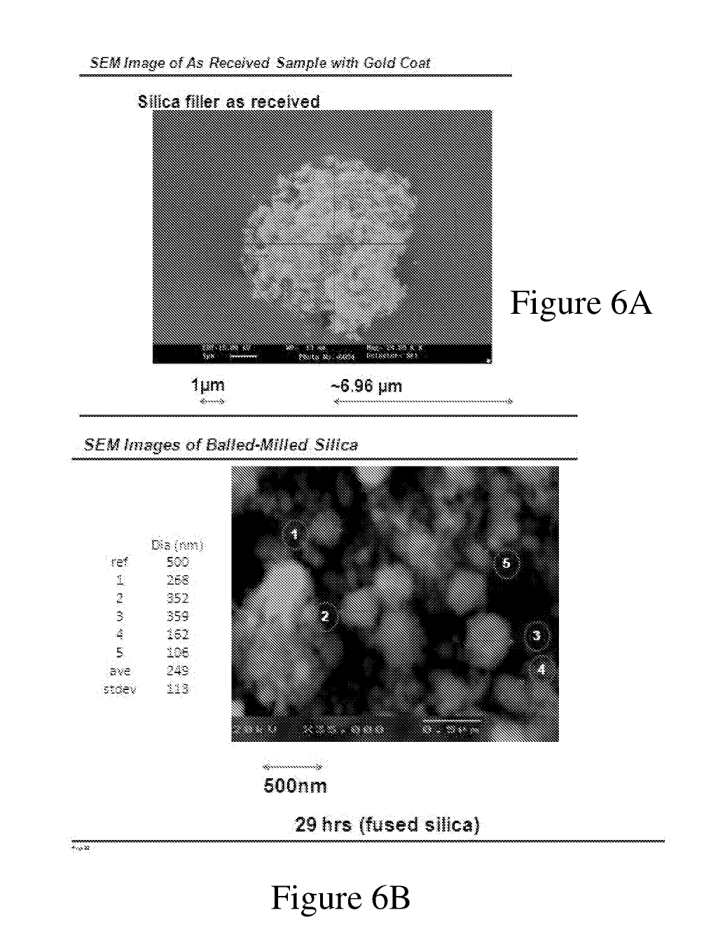

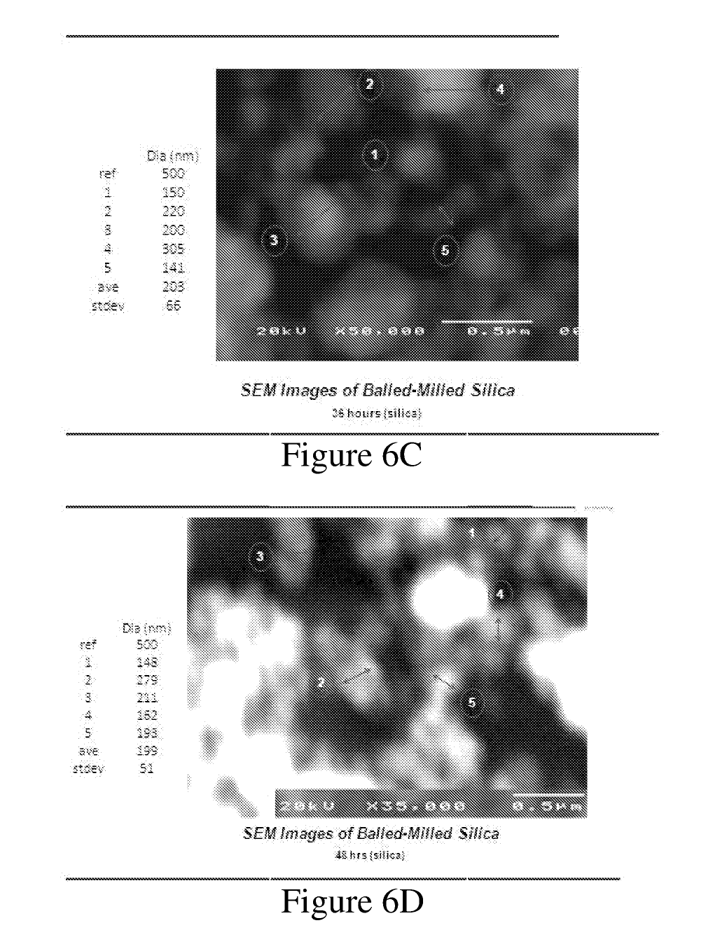

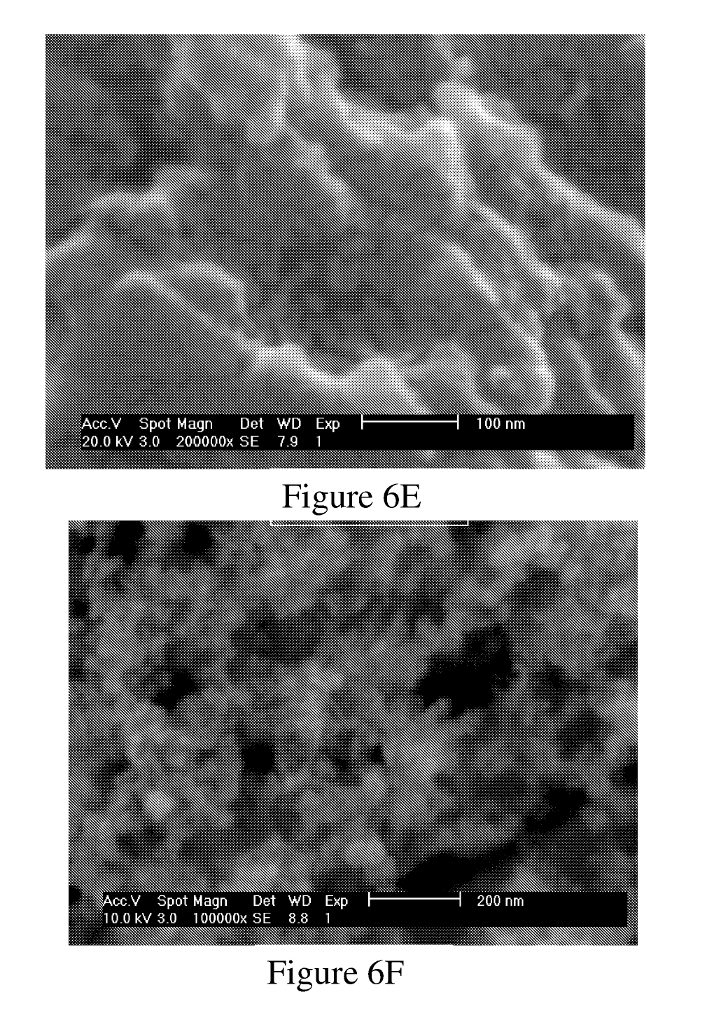

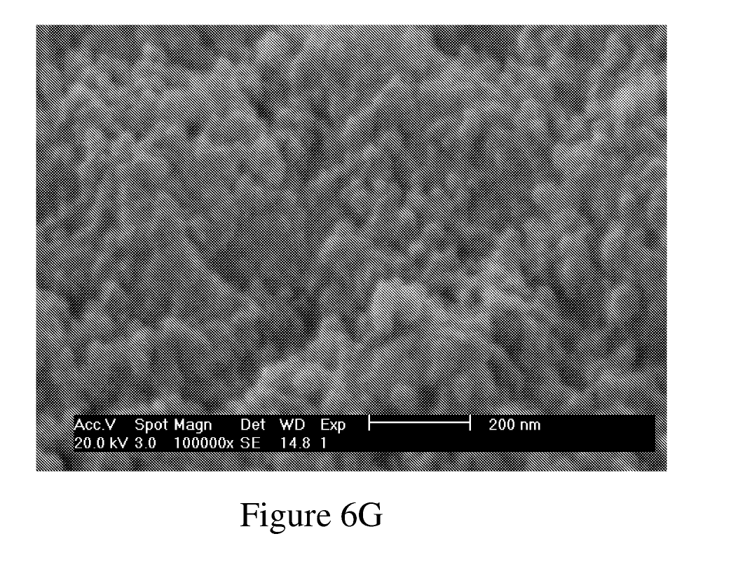

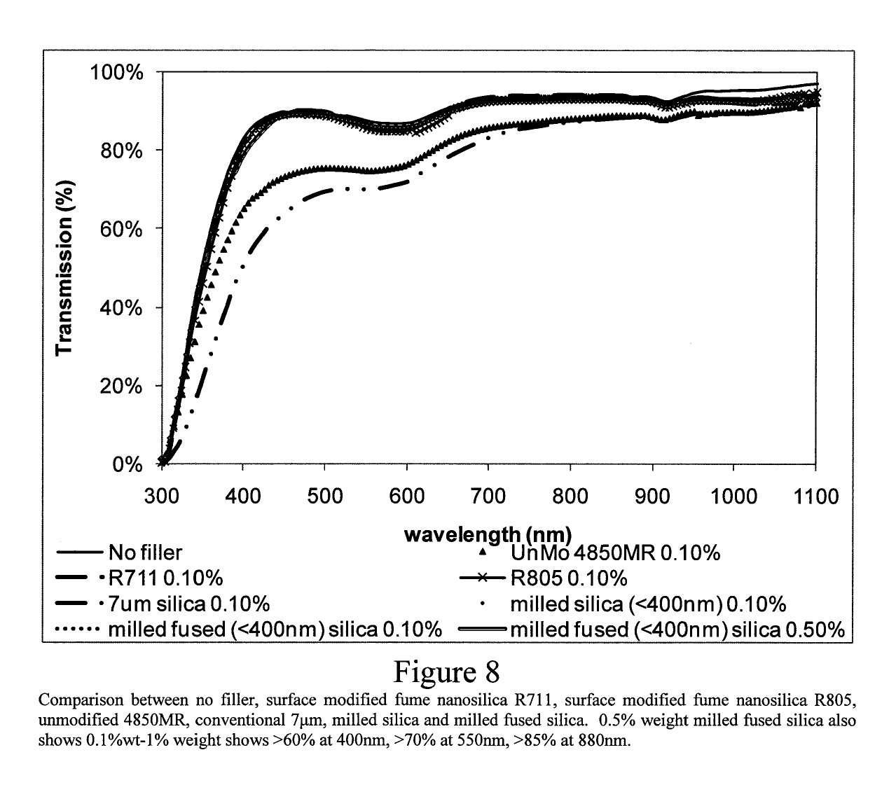

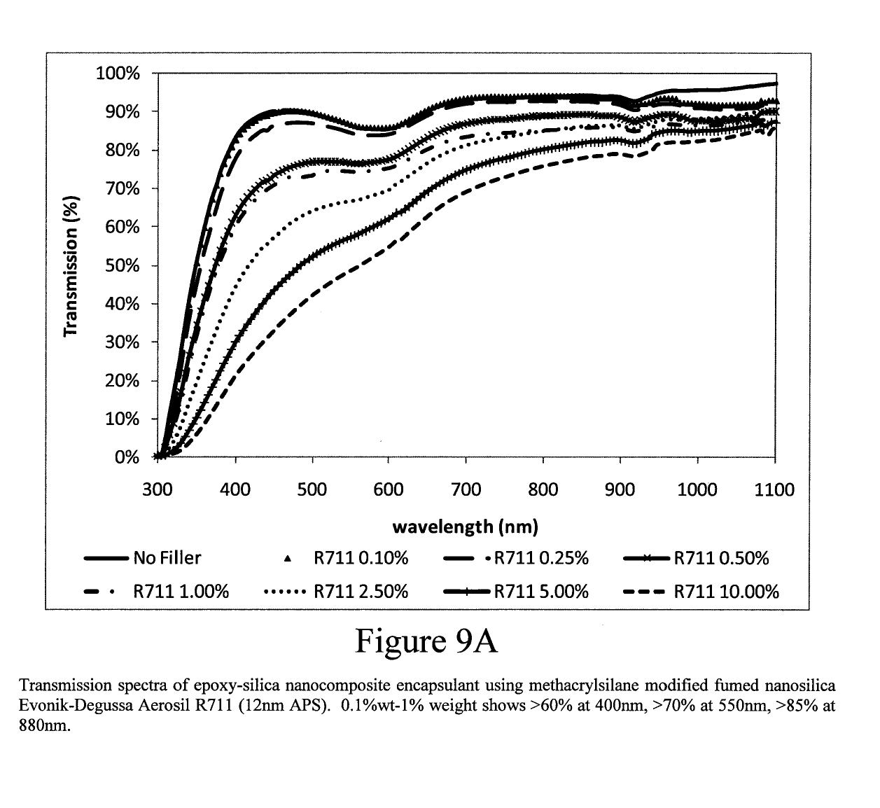

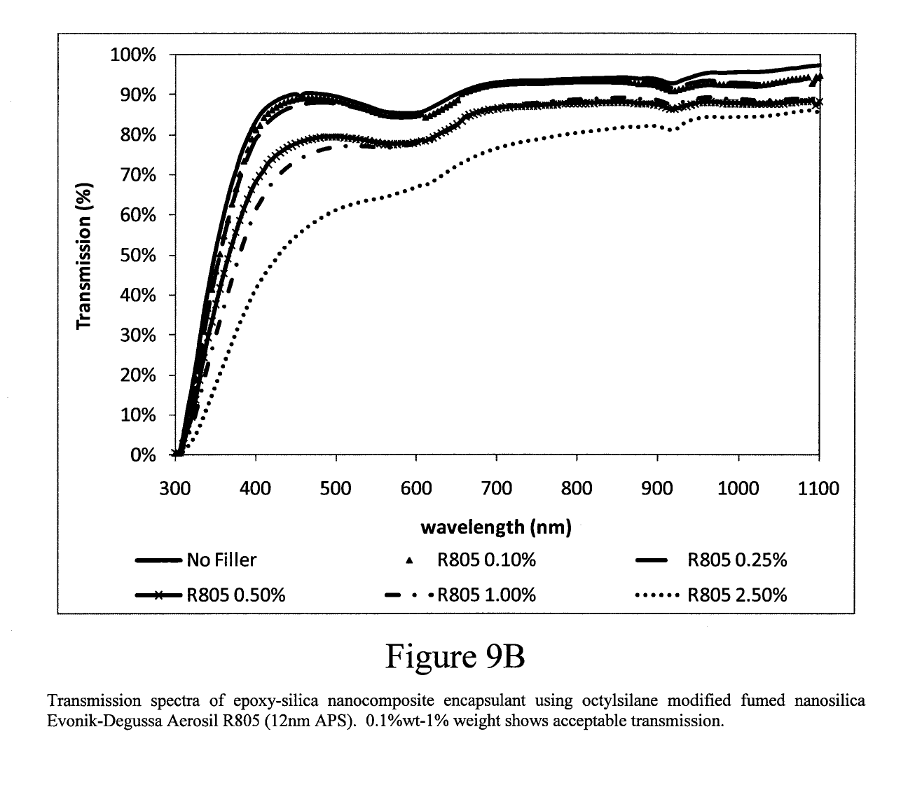

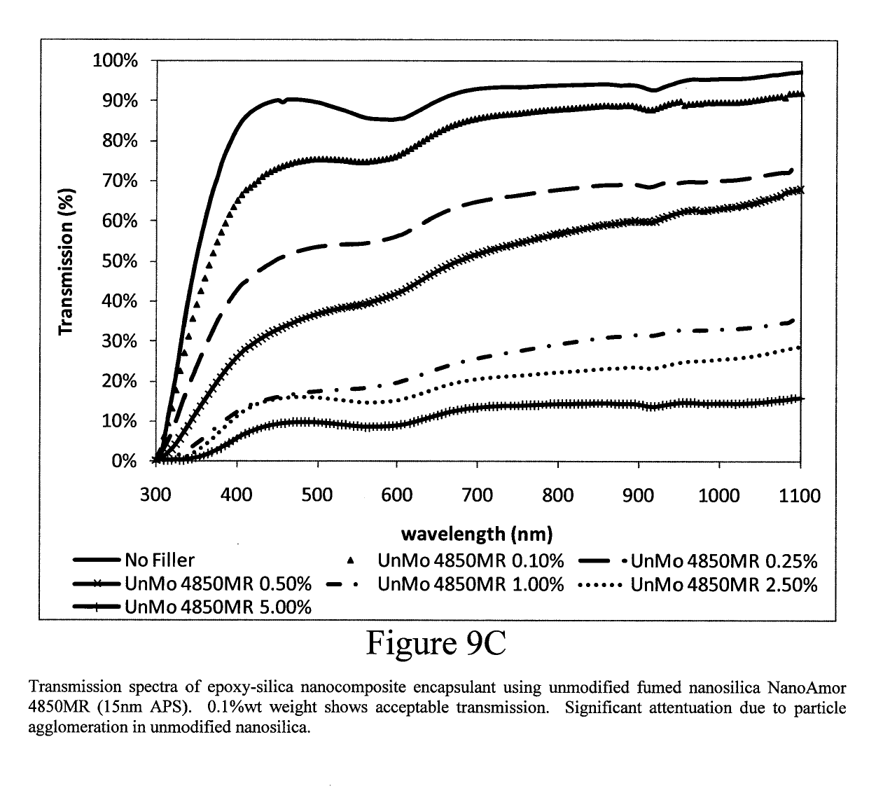

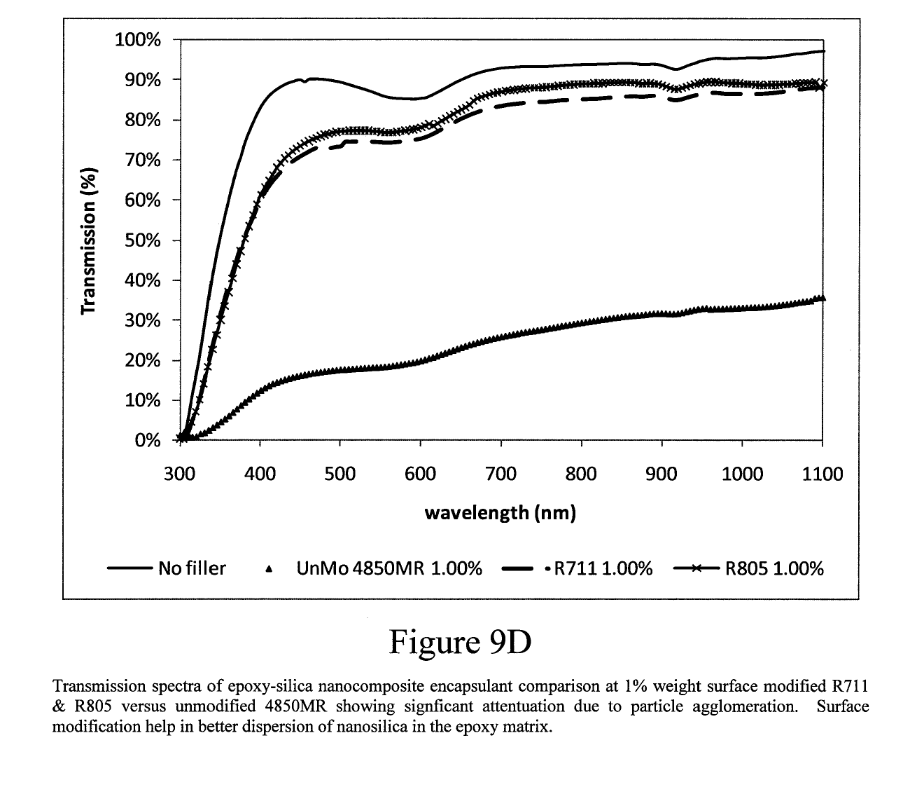

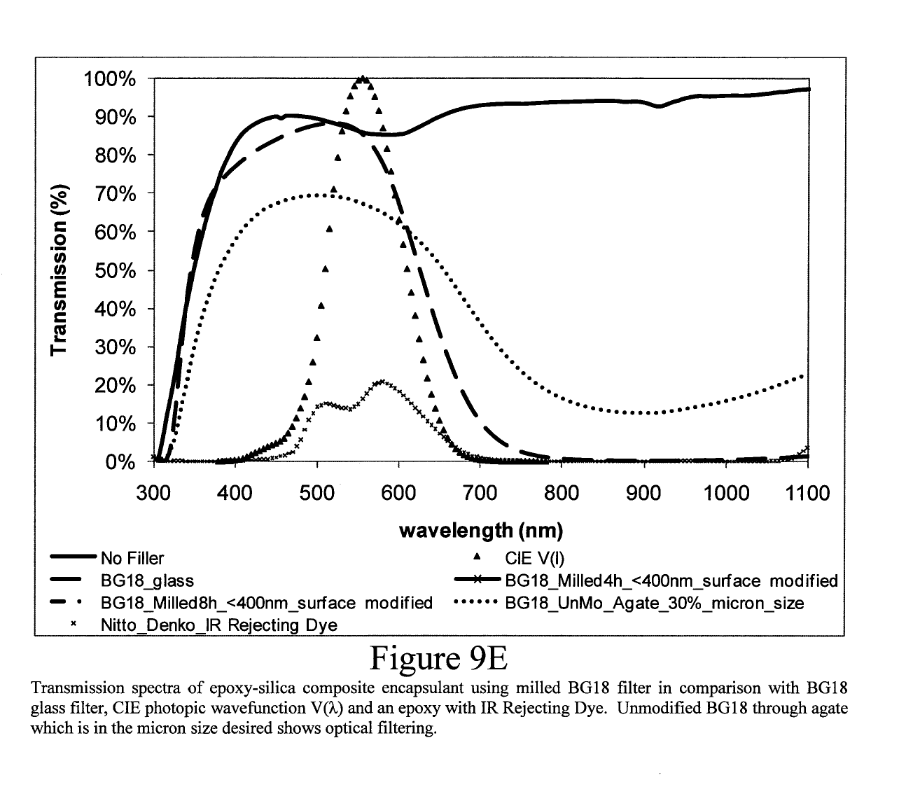

FIGS. 6A-6G show exemplary SEM and particle sizes obtained from ball milling of silica and fused silica in order to produce the nanoparticles (<100 nm) and submicron particles (<400 nm) used in the examples shown and described with respect to FIGS. 8 and 9A-9E. In particular, FIG. 6A shows as-received silica, e.g., having a ball size of approximately 7 μm, FIG. 6B shows fused silica after 29 hrs of ball milling, FIG. 6C illustrates fused silica after 36 hrs of ball milling, FIG. 6D illustrates fused silica after 48 hrs of ball milling. As illustrated, the ball milling process results in average particle sizes of substantially less than 400 nm. Further, FIG. 6E illustrates commercially available silica nanoparticles 99.5% APS 15 nm (NanoAmor Stock #: 4850MR), FIGS. 6F and 6G illustrate commercially available surface modified 12 nm silica nanoparticles Evonik-Degussa Aerosil R711 and R805, respectively.

In some examples, the nanoparticles and submicron particles can be surface modified. Surface modification can reduce particle aggregation and enhance interaction between the filler and epoxy or mold polymer matrix. Surface modification may include an organic coating and can be generated using a coupling agent such as a silanol or silane. Preferred modifications include GPTS or 3-methacryloxypropyltrimethoxysilane.

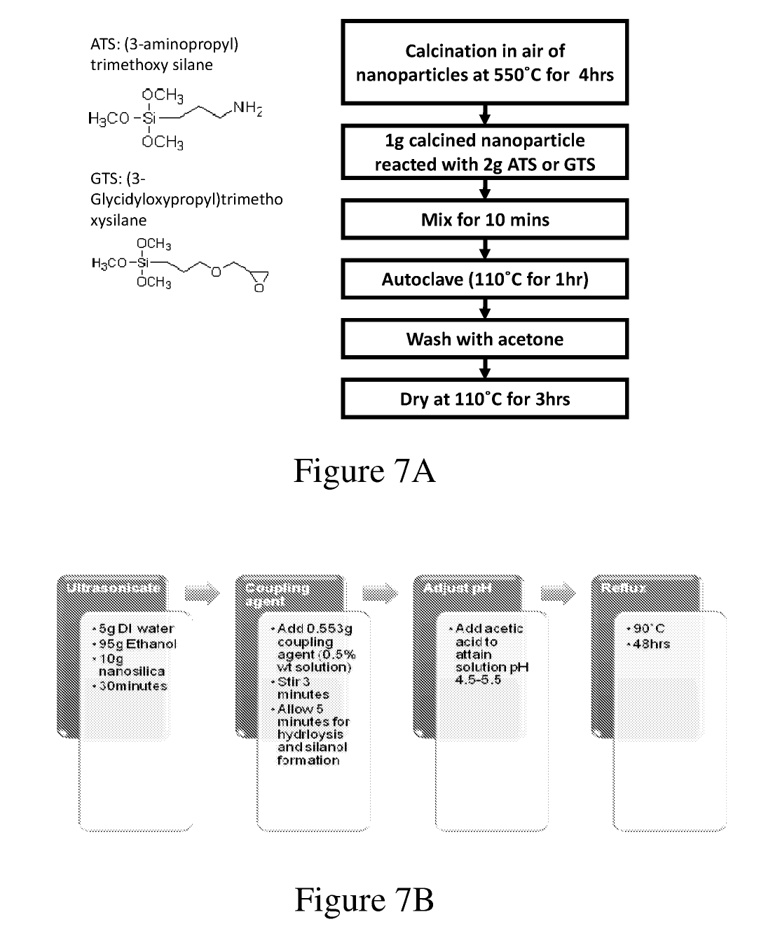

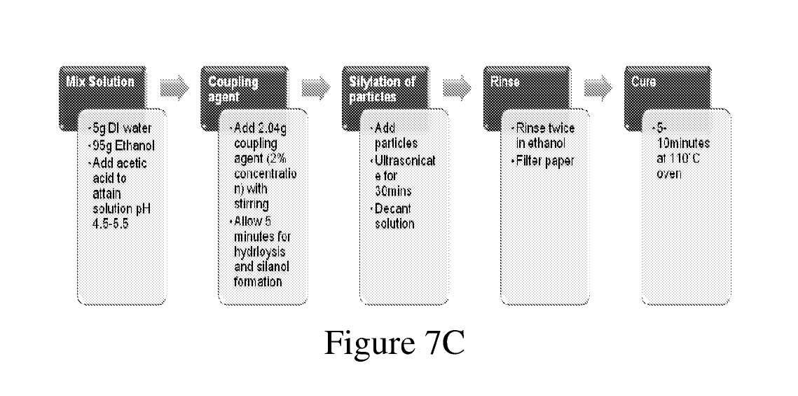

One approach for surface modification is illustrated in FIG. 7A. This surface modification method can also be used for submicron particles or a combination of nanoparticles and submicron particles. In this approach, the nanoparticles are subject to calcination in air at 550° C. for four hours. One gram of the calcined nanoparticles is reacted with two grams of GPTS and mixed for 10 minutes. The solution is then autoclaved for 1 hour at 110° C. followed by an acetone wash and drying at 110° C. for three hours.

Another approach for surface modification is illustrated in FIG. 7B. Initially, in this example, the nanoparticles are ultrasonicated within a solution of water and ethanol, for example. A coupling agent is then added and mixed therein, which may include Dynaslan® GLYMO, Dynaslan® 1189, and/or Dynaslan® 9896. The solution is allowed to stand for hydrolysis and silanol formation, and then the pH is adjusted, e.g., via the addition of acetic acid to attain a pH in the range of 4.5 to 5.5. Finally, reflux is performed, e.g., at 90° C. for 48 hours, leaving surface modified nanoparticles.

Yet another approach for surface modification is illustrated in FIG. 7C. Initially, in this example, a solution of water, ethanol, and acetic acid is prepared to attain a pH in the range of 4.5 to 5.5. A coupling agent is then added and mixed therein, which may include Dynaslan® GLYMO, Dynaslan® 1189, and/or Dynaslan® 9896. The solution is allowed to stand for hydrolysis and silanol formation. Nanoparticles are then added to the resulting solution and ultrasonicated, e.g., for 30 minutes. The solution is then decanted, rinsed, and the particles cured.

An embodiment of the present invention provides that there is no significant effect in the optical performance in terms of device transmission, emission, or responsivity in the wavelength range corresponding to approximately 300 nm-1100 nm. FIG. 8 illustrates exemplary results of transmission spectra of an epoxy-silica nanocomposite at 0.1% weight, with a comparison between no filler, surface modified fume nanosilica R711, surface modified fume nanosilica R805, unmodified 4850MR, conventional 7 μm, milled silica, and milled fused silica. As detailed in Table 1 below, R711 is surface modified nanosilica; in particular, 12 nm fumed silica surface modified with 3-Methacryloxypropyltrimethoxysilane, which is manufactured by Evonik Degussa as Aerosil® R711. Additionally, R805 is surface modified nanosilica; in this instance, 12 nm fumed silica surface modified with octyltrimethoxysilane, also manufactured by Evonik Degussa as Aerosil® R805. As seen in FIG. 8, the transmission spectra of an encapsulant with a nanocomposite filler (e.g., R711 and R805) is quite similar to an encapsulant with no filler. In contrast, an encapsulant with a filler using conventional silica particles (>3 μm) has substantially reduced transmission.

The following table provides a list of exemplary materials used in the examples provided herein.

TABLE 1
List of exemplary materials and manufacturer/part number where available:

| Material | Description | Manufacturer | Part Number |
|---|---|---|---|
| Nanoparticle | Nanopraticle SiO₂ (15 nm | NanoAmor | 4850MR |
| | average particle size) | | |
| | Micron-size particle SiO₂ | | |
| | Fused silica glass | Schott | |
| | Colored Filter (IR-Blocking | Y&M | Schott BG18 |
| | Filter) | | equivalent |
| Coupling Agent | GPTS: 3- | Evonik Degussa | Dynaslan ® |
| | glycidyloxypropyltrimethoxysilane | | GLYMO |
| | N-(n-Butyl)-3- | Evonik Degussa | Dynaslan ® 1189 |
| | aminopropytrimethoxysilane | | |
| | Oligomeric short-chain | Evonik Degussa | Dynaslan ® 9896 |
| | alkylfunctional silane | | |
| Solvent | Ethanol Absolute | Ajax Finechem | 214-2.5L PL |
| Thermosetting | Transparent Optoelectronic | Aptek | 6100-1 |
| Polymer | Encapsulant (two- | Laboratories | |
| | component epoxy resin cast | | |
| | material) | | |
| Surface | 12 nm fumed silica surface | Evonik Degussa | Aerosil ® R711 |
| Modified | modified with 3- | | |
| nanosilica | methacryloxypropyltrimethoxysilane | | |
| Surface | 12 nm fumed silica surface | Evonik Degussa | Aerosil ® R805 |
| Modified | modified with | | |
| nanosilica | octyltrimethoxysilane | | |

The coupling agent generally depends on the compatibility with the thermosetting polymer. However, GPTS or 3-methacryloxypropyltrimethoxysilane are the preferred coupling agent. Thermosetting polymer is a water clear optoelectronic encapsulant for casting technology. Other coupling agents include 3-aminopropyltrimethoxysilane (ATPS), octyltrimethoxysilane, N-(n-Butyl)-3-aminopropyltrimethoxysilane, or oligomeric short-chain alkylfunctional silane. Other thermosetting polymers include APM Technica Epicol 28, Oriem Technology LH0610e, Nitto-Denko cast epoxies, or electronic mold compounds.

Additional transmission spectra are illustrated in FIGS. 9A-9E for various exemplary nanocomposite encapsulants and weights. FIG. 9A illustrates transmission spectra of exemplary epoxy-silica nanocomposite encapsulant using methacrylsilane modified fumed nanosilica Evonik-Degussa Aerosil R711 (12 nm APS). The exemplary transmission spectra generally illustrates that 0.1% wt-1% weight shows >60% at 400 nm, >70% at 550 nm, >85% at 880 nm.

FIG. 9B illustrates transmission spectra of exemplary epoxy-silica nanocomposite encapsulant using octylsilane modified fumed nanosilica Evonik-Degussa Aerosil R805 (12 nm APS). The exemplary transmission spectra generally show that 0.1% wt-1% weight shows acceptable transmission.

FIG. 9C illustrates transmission spectra of exemplary epoxy-silica nanocomposite encapsulant using unmodified fumed nanosilica NanoAmor 4850MR (15 nm APS). The exemplary transmission spectra generally show that 0.1% wt weight shows acceptable transmission. Significant attenuation due to particle agglomeration is observed in unmodified nanosilica.

FIG. 9D illustrates transmission spectra of exemplary epoxy-silica nanocomposite encapsulant comparison at 1% weight surface modified R711 & R805 versus unmodified 4850MR. The spectra show significant attenuation due to particle agglomeration. As such, surface modification appears to help in better dispersion of the nanosilica in the epoxy matrix.

FIG. 9E illustrates transmission spectra of exemplary epoxy-silica composite encapsulant using milled BG18 filter in comparison with BG18 glass filter, CIE photopic wavefunction V(λ), and an epoxy with IR Rejecting Dye. Unmodified BG18 through agate, which is in the micron size desired, shows optical filtering.

A device in accordance with embodiments of the present invention may include a photodetector, photodiode, phototransistor, photodarlington, PhotoIC, PIN diode, laserdiode, light emitting diode (LED), infrared emitting diode (IRED), avalanche photodiode (APD), silicon avalanche photodiode (Si APD), high performance sensor (HPS), or any other optoelectronic device operating in the 300 nm-1100 nm wavelength range. The device may also include a leadframe including but not limited to copper-based and stainless steel-based frames, or substrates including but not limited to ceramic headers, metal headers and printed circuit boards (FR4, e-glass). The device may also include wirebond including but not limited to aluminum or gold wires. It may also any contain conducting or non-conducting die attach material. Optionally, the device may include an electronic junction coating or silicone-based coating.

Methods that can be used to assemble optoelectronic devices with the nanocomposite of the invention include but are not limited to die attach, wire bonding, encapsulation, solder dipping, Dam bar Trim and Form Singulation (DTFS), and electrical testing. Methods of encapsulating an optoelectronic device with the nanocomposite of the present invention include but are not limited to casting, molding, chip on board (COB), coating, glob top, sealing, and potting.

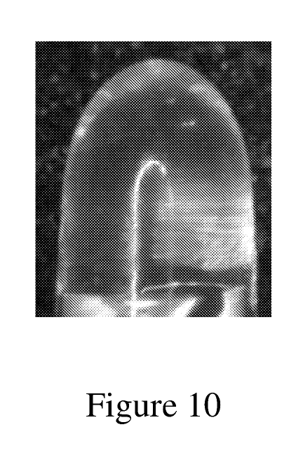

FIG. 10 is a photograph of an exemplary optoelectronic device packaged with 0.5% fused silica filler (<400 nm diameter).

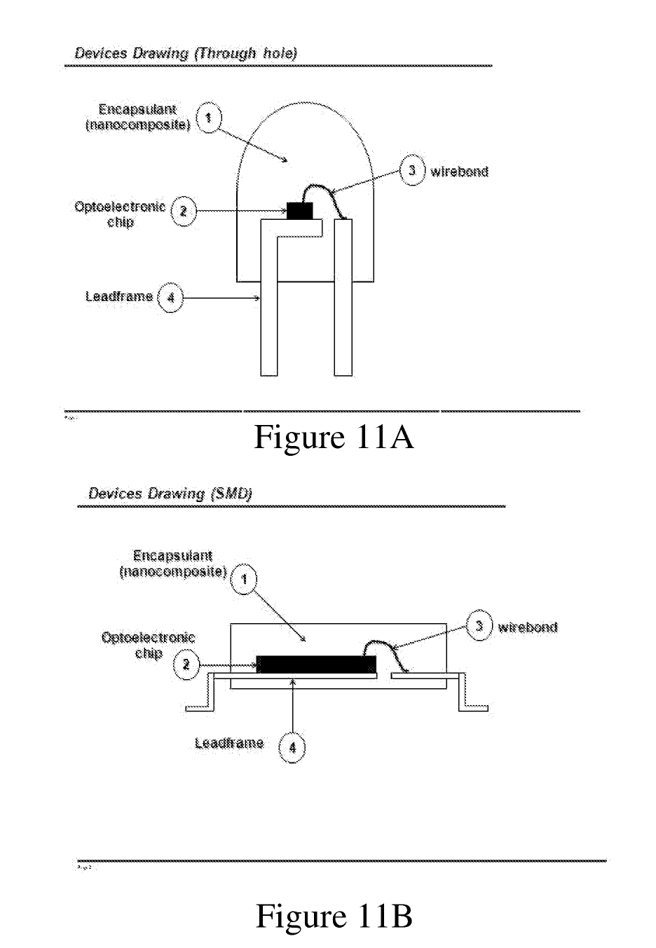

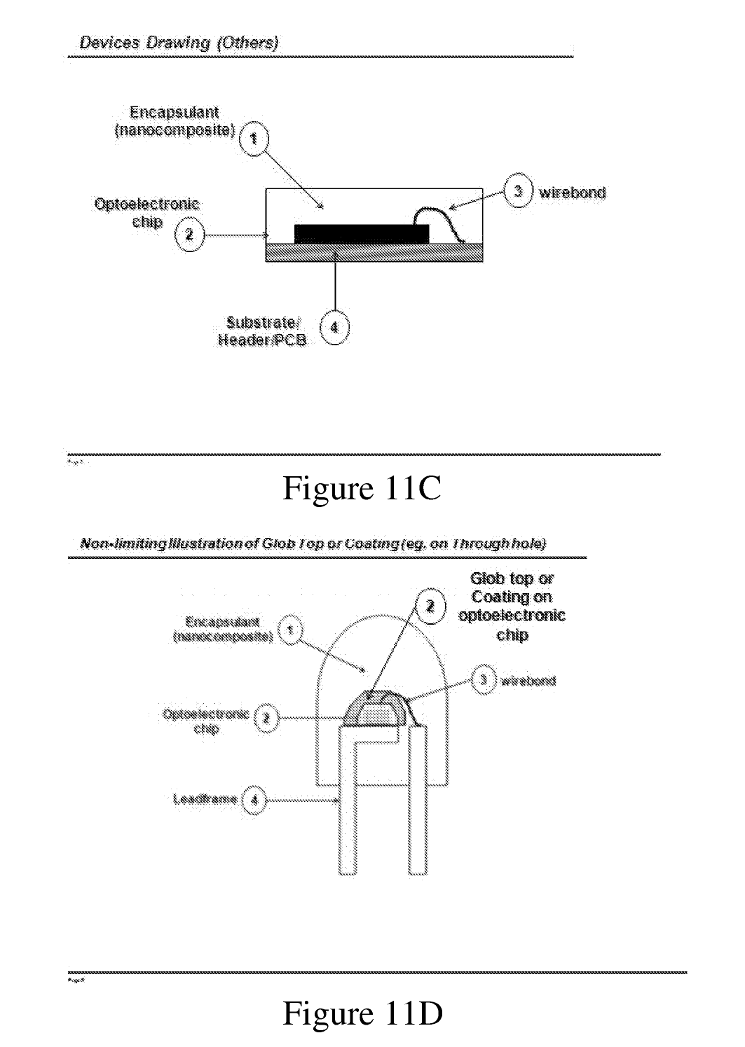

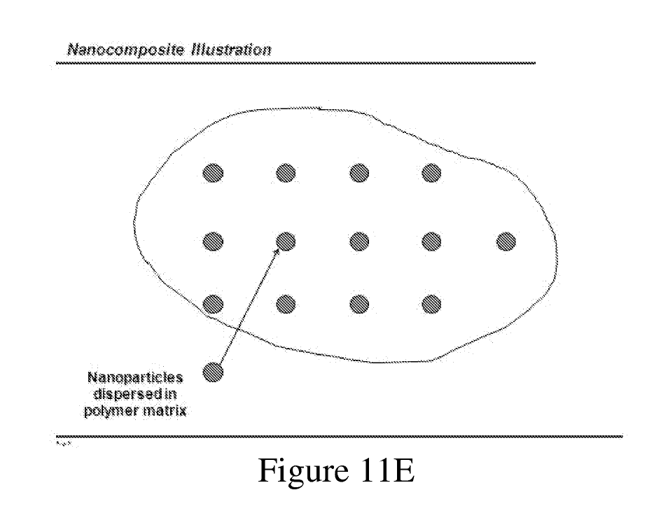

FIGS. 11A-11E illustrates exemplary types of optoelectronics devices in which the subject invention can be implemented. FIG. 11A illustrates a through-hole device having a leadframe 4 that is mounted to a circuit board. The chip 2 is mounted within the encapsulant 1 and attached to the leadframe 4 via wirebond 3. FIG. 11B illustrates a surface mounted device. FIG. 11C illustrates device wherein the chip 2 is mounted on a PCB header 4. FIG. 11D is similar to FIG. 11A but in this example, a color filter layer 10 is coated on top of the chip 2. This coating can be used to vary the transmission characteristics of the device. FIG. 11E is intended to depict the dispersion of the nanoparticles in the polymer matrix.

Examples provided herein may further provide an encapsulant and optoelectronic device having improved quality and reliability performance in accelerated stress test such as solder reflow and moisture sensitivity level, temperature, humidity and bias, hot temperature storage/operating life, highly accelerated stress test, thermal cycle, thermal shock, and dimensional stability. Examples may further provide for improved thermo-mechanical properties such as glass transition temperature, hardness, coefficient of thermal expansion, modulus of elasticity, tensile strength, ultimate strength and fracture strength, dimensional stability, and electrical properties such as volume resistivity and dielectric strength.

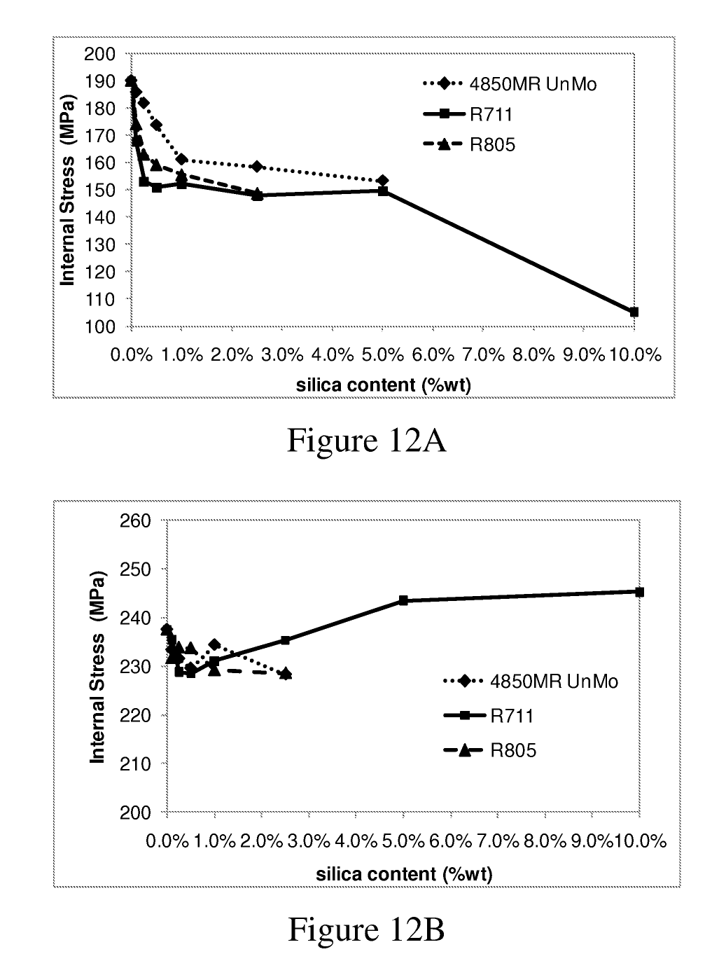

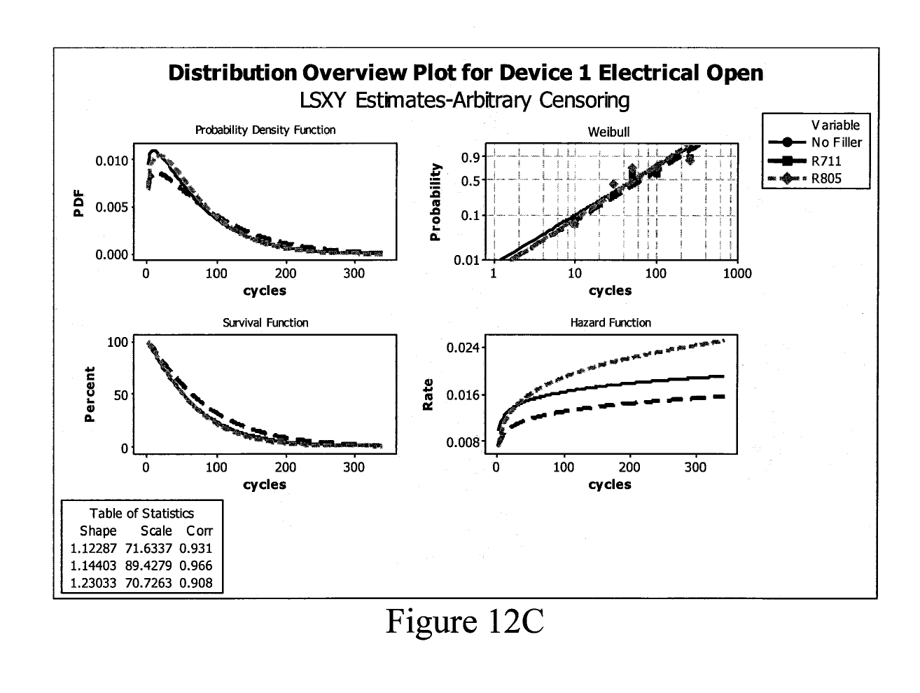

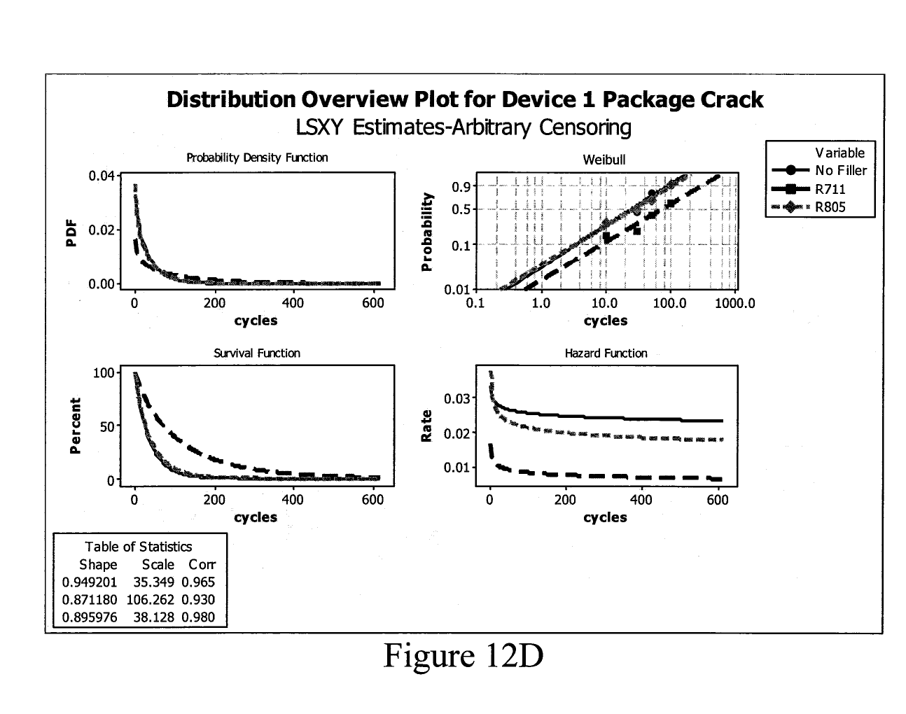

FIGS. 12A-12D, in conjunction with Tables 2-6 below, illustrate characterization measurements of exemplary modified and unmodified filler nanocomposite encapsulants described herein. Initially, Table 2 shows the summary of relevant characterization methods for various examples described herein.

TABLE 2
Characterization Methods

| Characterization | Method | Specimen dimensions |
|---|---|---|
| Thermal | | |
| Coefficient of Thermal | TMA ASTM E-831-03 | 5 mm × 5 mm × 3 mm |
| Expansion | Ramp R.T. to 200° C., | |
| | 10° C./min | |
| Linear Shrinkage | ASTM D-955-00 | 127 mm × 12.7 mm × |
| (Cast) | Length measured | 3.2 mm |
| | before and after curing | |
| Mechanical | | |
| Flexural Test | UTM ASTM D-790-03 | 127 mm × 12.7 mm × |
| | | 3.2 mm |

FIG. 12A and Table 3 illustrate internal stress due to linear shrinkage in epoxy-silica nanocomposites. As seen, there is significant decrease in internal stress due to curing shrinkage at <1% filler content. Generally, it is important to balance between lower linear shrinkage versus increasing modulus and brittleness and decreasing opacity. 10% filler content was found to have the lowest internal stress during cure with lowest shrinkage and highest modulus, but suffers brittleness and opacity.

TABLE 3
Shrinkage, Flexural Modulus, and Internal Stress during curing.
σ_{shrinkage} = (Shrinkage) × Modulus (E)

| | Shrinkage | | | Modulus (GPa) | | | Internal Stress (MPa) | | |
|---|---|---|---|---|---|---|---|---|---|
| % wt | 4850MR | | | 4850MR | | | 4850MR | | |
| loading | UnMo | R711 | R805 | UnMo | R711 | R805 | UnMo | R711 | R805 |
| 0.00% | 0.83% | 0.83% | 0.83% | 22.989 | 22.989 | 22.989 | 189.92 | 189.92 | 189.92 |
| 0.10% | 0.80% | 0.73% | 0.74% | 23.252 | 23.073 | 23.562 | 185.69 | 167.54 | 174.06 |
| 0.25% | 0.77% | 0.65% | 0.68% | 23.498 | 23.533 | 23.813 | 181.67 | 152.92 | 162.98 |
| 0.50% | 0.73% | 0.62% | 0.67% | 23.753 | 24.216 | 23.919 | 173.63 | 150.80 | 159.19 |
| 1.00% | 0.65% | 0.61% | 0.63% | 24.686 | 24.901 | 24.692 | 161.03 | 152.02 | 155.50 |
| 2.50% | 0.63% | 0.54% | 0.59% | 25.055 | 26.126 | 25.358 | 158.39 | 147.80 | 148.73 |
| 5.00% | 0.51% | 0.56% | | 26.396 | 27.204 | | 153.23 | 149.45 | |
| 10.00% | | 0.36% | | | 29.178 | | | 105.15 | |

FIG. 12B and Table 4 illustrate internal stress during thermal excursion or thermal shock from −40° C. to 115° C. due to CTE mismatch in epoxy-silica nanocomposites and substrate (e.g., copper 17 μm/(mm×° C.). As seen, there is an initial decrease in internal stress at <1% filler content. Net effect of lower CTE and higher modulus at increase filler content resulted to increase of internal stress at >1% filler content. Generally, a lower CTE and lower modulus is desired for a more robust plastic package.

TABLE 4
CTE, Flexural Modulus and Internal Stress during thermal cycle (−40° C. to 115° C.).
σ_{T} = (σ_{encap} − σ_{subs}) × ΔT × E_{avg}

| | CTE | | | | | | | | |
|---|---|---|---|---|---|---|---|---|---|
| | α₁ (μm/(mm×° C.)) | | | Modulus (GPa) | | | Internal Stress (MPa) | | |
| % wt | 4850MR | | | 4850MR | | | 4850MR | | |
| loading | UnMo | R711 | R805 | UnMo | R711 | R805 | UnMo | R711 | R805 |
| 0.00% | 83.66 | 83.66 | 83.66 | 237.53 | 237.53 | 237.53 | 237.53 | 237.53 | 237.53 |
| 0.10% | 81.66 | 82.83 | 80.43 | 233.04 | 235.43 | 231.66 | 233.34 | 235.43 | 231.66 |
| 0.25% | 80.56 | 79.73 | 80.35 | 231.50 | 228.81 | 233.82 | 231.50 | 228.81 | 233.82 |
| 0.50% | 79.34 | 77.87 | 80.04 | 229.52 | 228.47 | 233.72 | 229.52 | 228.47 | 233.72 |
| 1.00% | 77.06 | 75.16 | 76.98 | 229.79 | 224.49 | 229.56 | 234.34 | 231.11 | 229.17 |
| 2.50% | 75.78 | 75.11 | 75.15 | 228.27 | 235.32 | 228.55 | 228.27 | 235.32 | 228.55 |
| 5.00% | | 74.75 | | | 243.51 | | | 243.51 | |
| 10.00% | | 72.82 | | | 252.46 | | | 245.26 | |

Additionally, reliability stress test conditions were performed. In particular, temperature cycling (TC) was performed under conditions of −40° C. to 115° C. with 5 minutes dwell time at each extreme and <10 s ramp time to each extreme. The general purpose of the reliability stress test was to determine the ability of the encapsulant to withstand extreme temperature variations. FIG. 12C and Table 5 illustrate the reliability performance; in particular, Electrical Open Failure.

TABLE 5
Weibull parameters and Mean Time to Fail (MTTF)
for Electrical Open.

| Weibull | | | | |
|---|---|---|---|---|
| Parameters | | Accelerated | | |
| LSXY | | No Filler | R711 | R805 |
| Shape | β | 1.12287 | 1.14403 | 1.23033 |
| Scale | η | 71.63373 | 89.42790 | 70.7263 |
| MTTF | cycles | 106.765 | 133.230 | 104.967 |

As seen, R711 increased by 25% in terms of electrical open MTTF using Weibull analysis. R711 also has favorable electrical open BX life, Cumulative Reliability (R(t)), and Cumulative Failures (F(t)). Also illustrated in FIG. 12C are Weibull Distribution probability density function (PDF), survival, and hazard function for electrical open failures. As illustrated, no filler and R805 samples have no significant difference in performance, whereas R711 is more resilient to electrical open failures, which takes longer cycles to fail.

FIG. 12D and Table 6 illustrate the reliability performance; in particular, Package Crack

TABLE 6
Weibull parameters and Mean Time to Fail (MTTF)
for Electrical Open.

| Weibull | | | | |
|---|---|---|---|---|
| Parameters | | Accelerated | | |
| LSXY | | No Filler | R711 | R805 |
| Shape | β | 0.94920 | 0.87118 | 0.89598 |
| Scale | η | 35.34936 | 106.26198 | 38.1281 |
| MTTF | cycles | 40.217 | 113.894 | 36.191 |

As seen, R711 increased by 183% in terms of package crack MTTF using Weibull analysis. R711 also have favorable package crack BX life, Cumulative Reliability (R(t)), and Cumulative Failures (F(t)). FIG. 12D illustrates Weibull Distribution probability density function (PDF), survival, and hazard function for package cracking. As illustrated, no filler and R805 samples have no significant difference in performance, whereas R711 is more resilient to package crack, which takes longer cycles to fail.

The following lists of prior art documents relate to the use of nanocomposite materials with optoelectronic devices, and are incorporated herein by reference. Some of the documents teach using high index materials in the encapsulant in order to match the index of refraction of the semiconductor chip. To produce the best results, a very high load filling factor is required. In contrast, if the object of adding particulates is not for index matching but increased thermal and mechanical stability, a much lower loading factor is required, thereby saving costs. In addition, higher loading can reduce viscosity making fabrication more difficult. It is also noted that some of the prior art documents cited below do not suggest surface modification. It is believed that surface modification of the particles may be very important to achieve the best results.

U.S. Pat. No. 5,777,433 to Lester

U.S. Pat. No. 6,246,123 to Landers

US Publication No. 2005/0082691 to Ito

US Publication No. 2007/0221939 to Taskar

US Publication No. 2008/0012032 to Bhandarkar

The following list provides background articles related to nanocomposite formation and are incorporated herein by reference.
L. Cheng et al., “Manufacture of epoxy-silica nanoparticle composites and characterisation of their dielectric behavior,” Int. J. Nanoparticles (2008), Vol. 1, No. 1, pp. 3-13.
C-K. Min et al., “Functionalized mesoporous silica/polyimide nanocomposite thin films with improved mechanical properties and low dielectric constant,” Composites Science and Technology (2008), Vol. 68, pp. 1570-1578.
Y. Sun et al., “Study on mono-dispersed nano-size silica by surface modification for underfill applications,” Journal of Colloid and Interface Science (2005), Vol. 292, pp. 436-444.
C. L. Wu et al., “Silica nanoparticles filled polypropylene: effects of particle surface treatment, matrix ductility and particle species on mechanical performance of the composites,” Composites Science and Technology (2005), Vol. 65, pp. 635-645.
T. Wu et al., “The absorption and thermal behaviors of PET-SiO₂ nanocomposite films, Polymer Degradation and Stability (2006), Vol. 91, pp. 2205-2212.
C. Takai et al., “A novel surface designed technique to disperse silica nano particle into polymer,” Colloids and Surfaces A: Physicochem. Eng. Aspects (2007), Vol. 292, pp. 79-82.
A. Zhu et al., “Film characterization of poly(styrene-butylacrylate-acrylic acid)-silica nanocomposite,” Journal of Colloid and Interface Science (2008), Vol. 322, pp. 51-58.

It should be recognized that a number of variations of the above-identified embodiments will be obvious to one of ordinary skill in the art in view of the foregoing description. Accordingly, the invention is not to be limited by those specific embodiments and methods of the present invention shown and described herein. Rather, the scope of the invention is to be defined by the following claims and their equivalents.

What is claimed is:

1. A nanocomposite composition for encapsulating an optoelectronic device, the nanocomposite composition comprising:
an encapsulant, wherein the encapsulate is 10-99.99% by weight of the nanocomposite composition; and
a filler, comprising particles having a diameter of less than 400 nm, wherein the particles comprise a surface modification, and the filler is 0.01-90% by weight of the nanocomposite composition.

2. A nanocomposite composition as recited in claim 1, wherein the encapsulant is comprised of an optoelectronic-grade material selected from the group consisting of: epoxy resin, mold compound, and silicone-based polymer.

3. A nanocomposite composition as recited in claim 1, wherein the encapsulant further comprises a dye or filter pigment for additional optical filtering.

4. A nanocomposite composition as recited in claim 1, wherein the particles are comprised of a material selected from the group consisting of: SiO₂, Al₂O₃, TiO₂, ZnO, ZrO₂, MgO, YtO, CeOx, Sb₂O₃, SnO, Bi₂O₃, ZnSe, ZnS, CsI, AlN, TiN, GaN, SiN, fused silica, borosilicate, quartz, and colored glass.

5. A nanocomposite composition as recited in claim 1, wherein the surface modification comprises a silanol or a silane.

6. A nanocomposite composition as recited in claim 5, wherein the silane comprises 3-methacryloxypropyltrimethoxysilane, octyltrimethoxysilane, or 3-glycidyloxypropyl trimethoxysilane (GTS).

7. A nanocomposite composition as recited in claim 1, wherein the encapsulant is 95-99.9% by weight, and the filler is 0.01-5% by weight, of the nanocomposite composition.

8. A nanocomposite composition as recited in claim 7, wherein the encapsulant is 99.9% by weight, and the filler is 0.01% by weight, of the nanocomposite composition.

9. A nanocomposite composition as recited in claim 7, wherein the encapsulant is 99.5% by weight, and the filler is 0.5% by weight, of the nanocomposite composition.

10. A nanocomposite composition as recited in claim 7, wherein the encapsulant is 99% by weight, and the filler is 1% by weight, of the nanocomposite composition.

11. A nanocomposite composition as recited in claim 7, wherein the encapsulant is 97.5% by weight, and the filler is 2.5% by weight, of the nanocomposite composition.

12. A nanocomposite composition as recited in claim 7, wherein the encapsulant is 95% by weight, and the filler is 5% by weight, of the nanocomposite composition.

13. A nanocomposite composition as recited in claim 1, where the particles further comprise particles having a diameter between 1 nm and 400 nm.

14. A method for encapsulating an optoelectronic device with the nanocomposite composition as recited in claim 1, the method comprising a technique selected from the group consisting of: casting, molding, chip on board (COB), coating, glob top, sealing, and potting.

15. An optoelectronic device comprising the nanocomposite composition as recited in claim 1, wherein the optoelectronic device is selected from the group consisting of: photodetector, photodiode, phototransistor, photodarlington, PhotoIC, PIN diode, laserdiode, light emitting diode (LED), infrared emitting diode (IRED), avalanche photodiode (APD), silicon avalanche photodiode (Si APDs), high performance sensor (HPS), and semiconductor integrated circuit (IC).

16. A nanocomposite composition comprising:
an encapsulant, wherein the encapsulate is 20-99.99% by weight of the nanocomposite composition; and
a filler, comprising silica (SiO₂) particles having a diameter of less than 400 nm and greater than 1 nm, wherein the filler is 0.01-80% by weight of the nanocomposite composition, wherein the nanocomposite composition is for encapsulating a photodetector or light emitting diode.

17. A nanocomposite composition as recited in claim 16, wherein the particles comprise a surface modification.

18. A nanocomposite composition as recited in claim 17, wherein the surface modification comprises a silanol or a silane.

19. A nanocomposite composition as recited in claim 16, wherein the encapsulant is 95-99.9% by weight, and the filler is 0.01-5% by weight, of the nanocomposite composition.

20. A method for encapsulating an optoelectronic device with the nanocomposite composition as recited in claim 16, the method comprising a technique selected from the group consisting of: casting, molding, chip on board (COB), coating, glob top, sealing, and potting.

21. A nanocomposite composition comprising:
an encapsulant, wherein the encapsulate is 20-99.9% by weight of the nanocomposite composition; and
a filler, comprising alumina (Al₂O₃) particles having a diameter of less than 400 nm and greater than 1 nm, wherein the filler is 0.01-80% by weight of the nanocomposite composition,
wherein the nanocomposite composition is for encapsulating a photodetector.

22. A nanocomposite composition as recited in claim 21, wherein the particles comprise a surface modification.

23. A nanocomposite composition as recited in claim 22, wherein the surface modification comprises a silanol or a silane.

24. A nanocomposite composition as recited in claim 21, wherein the encapsulant is 95-99.9% by weight, and the filler is 0.01-5% by weight, of the nanocomposite composition.

25. A method for encapsulating an optoelectronic device with the nanocomposite composition as recited in claim 21, the method comprising a technique selected from the group consisting of: casting, molding, chip on board (COB), coating, glob top, sealing, and potting.

26. A nanocomposite composition comprising:
an encapsulant, wherein the encapsulate is 20-99.9% by weight of the nanocomposite composition; and
a filler, comprising titanium dioxide (TiO₂) particles having a diameter of less than 400 nm and greater than 1 nm, wherein the filler is 0.01-80% by weight of the nanocomposite composition, wherein the nanocomposite composition is for encapsulating a photodetector.

27. A nanocomposite composition as recited in claim 26, wherein the particles comprise a surface modification.

28. A nanocomposite composition as recited in claim 27, wherein the surface modification comprises a silanol or a silane.

29. A nanocomposite composition as recited in claim 26, wherein the encapsulant is 95-99.9% by weight, and the filler is 0.01-5% by weight, of the nanocomposite composition.

30. A method for encapsulating an optoelectronic device with the nanocomposite composition as recited in claim 26, the method comprising a technique selected from the group consisting of: casting, molding, chip on board (COB), coating, glob top, sealing, and potting.

31. A nanocomposite composition comprising:
an encapsulant, wherein the encapsulate is 20-99.9% by weight of the nanocomposite composition; and
a filler, comprising zinc oxide (ZnO) particles having a diameter of less than 400 nm and greater than 100 nm, wherein the filler is 0.01-80% by weight of the nanocomposite composition,
wherein the nanocomposite composition is for encapsulating a photodetector or light emitting diode.

32. A nanocomposite composition as recited in claim 31, wherein the particles comprise a surface modification.

33. A nanocomposite composition as recited in claim 32, wherein the surface modification comprises a silanol or a silane.

34. A nanocomposite composition as recited in claim 31, wherein the encapsulant is 95-99.9% by weight, and the filler is 0.01-5% by weight, of the nanocomposite composition.

35. A method for encapsulating an optoelectronic device with the nanocomposite composition as recited in claim 31, the method comprising a technique selected from the group consisting of: casting, molding, chip on board (COB), coating, glob top, sealing, and potting.

36. A nanocomposite composition comprising:
an encapsulant, wherein the encapsulate is 10-99.9% by weight of the nanocomposite composition; and
a filler, comprising colored glass particles having a diameter of 400 nm to 100 μm, and the filler is 0.01-90% by weight of the composition,
wherein the nanocomposite composition is for encapsulating a photodetector or light emitting diode.

37. A nanocomposite composition as recited in claim 36, wherein the particles comprise a surface modification.

38. A nanocomposite composition as recited in claim 37, wherein the surface modification comprises a silanol or a silane.

39. A nanocomposite composition as recited in claim 36, wherein the encapsulant is 95-99.9% by weight, and the filler is 0.01-5% by weight, of the nanocomposite composition.

40. A method for encapsulating an optoelectronic device with the nanocomposite composition as recited in claim 36, the method comprising a technique selected from the group consisting of: casting, molding, chip on board (COB), coating, glob top, sealing, and potting.
